(19) United States
(12) Patent Application Publication
(10) Pub. No.: US 2005/0151457 A1
(43) Pub. Date: Jul. 14, 2005

(54) Method of manufacturing a flat panel display

(76) Inventors: Marcus Schrijvers, Heerlen (NL); Claudia Mutter, Heerlen (NL); Gerardus A.J Hoeymans, Eindhoven (NL); Thomas Nicolaas Maria Bernards, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/514,172

(22) PCT Filed: May 12, 2003
(86) PCT No.: PCT/IB03/01938

(30) Foreign Application Priority Data
May 15, 2002 (EP) 02076933.7

(51) Int. Cl. H01J 29/10

(52) U.S. Cl. 313/461

(57) ABSTRACT

The arrangement (100) enables the provision of gas pressure for laminating a first and a second substrate (1,2) of a flat panel display. The fluid is provided in a cavity (110) defined by a second carrier plate (102) and a ring-shaped protrusion (103) of the arrangement (100), and the outer face (22) of the second substrate (2). The substrates (1,2) with a display element (8) in between of them, are laminated with sealing material (7), that preferably comprises spacers to keep the inner faces (11,21) of the substrates (1,2) at a predetermined distance of less than 50 μm.

The invention relates to a method of manufacturing a flat panel display comprising a first and a second substrate in between of which a display element is present, the substrates having an inner face and an outer face and facing each other with their inner faces, which method comprises the steps of:
providing a sealing material at the inner face of at least one of the substrates;
laminating the substrates by applying a mechanical force at the outer face of at least one of them, and
curing the sealing material.

The invention also relates to an arrangement for laminating a first and a second substrate in between of which a display element is present, provided with a first carrier plate for the first substrate and a second carrier plate to which the second substrate can be attached, and means for moving the carrier plates towards each other to laminate the first and second substrate.

The invention further relates to a flat panel display comprising a first and a second glass substrate in between of which an electroluminescent display element with an organic electroluminescent layer is present, the substrates having an inner face and an outer face and facing each other with their inner faces and being laminated together with a layer of sealing material, the display element being hermetically enclosed by the first and the second substrate and the layer of sealing material.

Such a method is known from JP-A 2001-189191. In the known method the second substrate is a closing plate, which consists of a stainless steel material and has a box-like shape. This closing plate is laminated to the first substrate of glass, at the inner face of which the—in this case electroluminescent—display element has been provided. The lamination takes place under a vacuum or non-oxidizing and a low humidity ambient atmosphere in order to prevent deterioration of the display element. By mechanical action of a fixture holding the second substrate, the first and second substrate are contacted and laminated. The sealing material is cured by means of ultraviolet irradiation.

It is a disadvantage of the known display that its thickness is large due to the box-like shape of the closing plate. In order to circumvent this, a substantially flat closing plate may be used, such as a glass plate, such as known from JP-A 2001-319775. Such a flat closing plate has the additional advantage that the lamination can be done at a plate level, such as a substrate having a diameter of 6″ (15 cm) or larger.

However, it has been found in experiments leading to the invention, that the lifetime of the manufactured devices is low, if the closing plate of stainless steel material is just replaced by a substantially flat closing plate.

It is therefore a first object of the invention to provide a method of manufacturing a flat panel display of the type mentioned in the opening paragraph, wherein the resulting devices are provided with a substantially flat second substrate and have an acceptable lifetime.

The first object is realized in that a fluid is provided at the outer face of the second substrate to apply the mechanical force homogeneously over the substrate.

Through the use of a fluid for applying the mechanical force at the outer face of the second substrate, the applied force is homogeneous throughout the entire substrate. As the result thereof, it has been found that the lifetime is considerable increased. As a measure for the lifetime the size of a representative unit of an electroluminescent display element—to which will also be referred to as pixel hereinafter—is used. Directly after the lamination the pixel size is between 260 and 270 μm. After an extreme life time test of 21 days at elevated temperature and humidity the pixels of the flat panel displays that were manufactured by applying direct mechanical force had shrunk with 10 to 30%. The pixels of the flat panel displays manufactured with the method of the invention had however maintained a pixel size of more than 260 μm.

It is an advantage of the method of the invention, that it can be applied at plate level. This has the advantage that assembly of the individual closing plates is not necessary anymore, leading to a substantial reduction in cost price. Another advantage of the method of the invention is that the resulting flat panel displays can be very flat.

Another advantage of the method of the invention is that no white areas are present in the layer of sealing material after curing. Such white areas were present when using direct mechanical force. The white areas were characterized as bubbles. The inventors believe that these developed because locally a too high pressure was applied.

A further advantage of the method of the invention is that damages of the second substrate due the contact between the second substrate and the second carrier plate are prevented. Therewith the yield is increased immediately. It is prevented as well, that microcracks in the substrate, preferably of glass, come into existence that could develop into cracks during the lifetime of the flat panel display. If such cracks would develop after integration of the display into a consumer electronics device, the device must be repaired. This would give substantial costs and be detrimental to the image of quality.

In an advantageous embodiment of the method of the invention an arrangement having a first and a second carrier plate is provided, to which second carrier plate a ring-shaped protrusion is attached. The first substrate is provided with its outer face on the first carrier plate, and the second substrate is attached with its outer face to the second carrier plate, such that a cavity is present between the second substrate, the second carrier plate and the ring-shaped protrusion. The fluid is provided into the cavity. In this embodiment the fluid is provided in a cavity with a limited volume, with the second carrier plate and the second substrate as main boundaries.

It is an advantage of this embodiment that the limited volume can be filled quickly, so that the laminating does not take too much time. It is another advantage thereof that the cavity is essentially integrated into parts—the second substrate and the second carrier plate—that are in any case present. It is a further advantage that the fluid can be provided at limited areas of the second substrate only, e.g. particularly those areas at which the sealing material is provided. Therewith it is prevented that second substrate and/or the display element is damaged due to bending of the second substrate. It is another advantage, that flat display panels of varying shape and size can be manufactured with the same arrangement and within the same substrates. In the prior art method the closing plates are of one size only and must be laminated with a size-specific apparatus. In the method of the invention the size and shape of the flat panel display is determined by the design and the separation.

It is preferred that the fluid is a gas that is provided into the cavity through an aperture in the second carrier plate. Although the fluid can be a fluid, such as an alcohol, it is preferably that it is a gas. With a gas the pressure on the second substrate can be provided very homogeneously, and it is relatively easy to provide a pressure build-up through the addition of gas or an increase in temperature. Further on, gas will not wet the outer surface of the second substrate. It is preferred that the gas is a inert gas, such as N₂, Ar, Ne or the like. It will be clear that is not preferred that the gas is or contains O₂ or H₂O. Principally, it is possible that the gas is supplied through a connection in the ring-shaped protrusion.

However, this protrusion is preferably flexible and of rubber, such as to provide a good closure between the second substrate and the second carrier. Therefore, it is preferable that the second carrier plate contains an aperture and means for attaching a supply-pipe for the gas. The means for attaching are per se well-known and preferably such that the supply-pipe can be removed as well.

In a further embodiment the cavity is further bounded by an inner ring-shaped protrusion which is attached to the second carrier plate, so as to provide mechanical force at limited areas of the second substrate only. With this embodiment bending of the second substrate at areas that are not to be laminated are prevented. This is relevant, if the display element has a large size, for instance 10″ (25 cm). Such large-sized display elements are suitable for use in monitors, televisions and the like. The application of mechanical force—especially gas pressure—is of particular relevance for an electroluminescent display element with an organic electroluminescent layer. Such electroluminescent display element can be provided in full-colour and has a sharp contrast, and is therefore a high-quality alternative to a liquid crystalline display element. However, the organic electroluminescent layer is very sensitive to oxygen and moisture, so that a hermetically enclosure, as provided with the method of the invention, is necessary to attain the required lifetime. For sake of clarity it is stated that the term ‘organic electroluminescent layer’ is meant to include a polymeric electroluminescent layer.

In another embodiment a second cavity is present between the second substrate and the second carrier plate, the second cavity being bounded between a second ring-shaped protrusion that is attached to the second carrier plate. This embodiment is very suitable, if the first and second substrate have a very large size, for instance 14″ (35 cm), and will be separated into a plurality of individual flat panel displays after laminating the substrates and curing the sealing material.

The substrates may be of varying thickness and material. Suitable materials are for example ceramic materials, glass and optionally filled organic layers through which humidity and gases cannot diffuse. If the display elements are present at the inner face of the second substrate, this substrate will be transparent. It is preferred that the first and second substrates are made of glass. The thickness of the substrates is generally in between of 20 μm and 2.0 mm, but may be thinner or thicker. The substrates need not to be equally thick. If the first substrate is the closing plate, it further may have deepened parts, in which a getter for the moisture can be provided. Such deepened part is for instance provided with powder blasting or etching. The display elements are then present at the inner face of the second substrate. Spacers can be present next to the display elements in order to protect it while laminating the first and second substrates. Alternatively, the sealing material has a larger thickness than the display element, and fulfills the spacer function. However this may be reversed, or some functionality, such as a black layer or an interconnect layer may be present at the inner face of the second substrate. The first and second substrate can be rigid, but also flexible.

It is further preferred that the sealing material comprises spacers, so as to bring the inner faces of the first and second substrates at a predetermined distance of each other. A suitable distance is 50 μm or less. Particularly suitable is a distance of less than 20 μm. The use of spacers in the sealing material has been found to be very effective in providing the first and second substrates of glass at a distance, which is substantially the same over the whole substrate. The sealing material is preferably an organic material. As stated in WO-A-00/76276 the layer of sealing material has preferably a width of at least 0.2 mm. This large width in combination with the reduced thickness provides to a strongly increased resistance to diffusion of moisture through the layer of sealing material.

The sealing material is preferably a UV-curable sealing material, that is cured with ultraviolet irradiation. Such UV-curing has the advantage above thermal curing, that no expansion of materials—especially gases—present between the first and second substrates takes place, with the risks of the forming of any cracks or pores, and that the display element may be damaged. Although measures can be taken to prevent such undesired side-effects, they are in essence contrary to a hermetical sealing. Alternatively, curing by localized heating, for example with laser light, is an option.

The method of the invention can be used for any kind of flat display elements, such as liquid crystalline and LCOS. It is however especially suitable for organic electroluminescent display elements due to their sensitivity for moisture. The resulting flat panel display is found to be effective to limit the influence of moisture. This is even the case for electroluminescent display elements, in which the individual pixels are separated by protruding structures, for example of resist material. Such structures are provided to separate the pixels in a display elements. They may act as internal shadow masks for cathode separation and as barriers during inkjet printing of the pixels. However, at the side faces of such structures the organic electroluminescent layer lies at the surface. This has the effect that the penetration of moisture is relatively easy as compared to the display element provided with a single, large pixel. Due to the homogeneous application of mechanical force in the method of the invention, and the small distance between the inner faces of the first and second substrates, the resulting flat panel display has nevertheless a good resistance against moisture and an excellent lifetime.

It is a second object of the invention to provide an arrangement of the type mentioned in the opening paragraph for use in the method of the invention. The second object is realized in that the second carrier plate is provided with:
mechanical attachment means such that after attaching the second substrate a cavity is present between the second substrate and the second carrier plate,
a ring-shaped protrusion, that acts as side-wall of the cavity, and
supply means to provide a fluid into the cavity.

With the arrangement of the invention a mechanical force can be applied homogeneously on a substrate. It is therewith advantageous that the cavity for the fluid is formed by parts two of which are present in the arrangement in any case. The third part, the ring-shaped protrusion, helps to provide an excellent closure. It is preferably of a flexible material, such as rubber. This third part is attached to the second carrier plate with chemical means, such as adhesive, or mechanical means, such as a groove.

In a suitable embodiment a second ring-shaped protrusion is attached to the second carrier plate, to act as an inner boundary of the cavity or to define a second cavity. This embodiment allows the application of the mechanical force at limited areas of the substrates only.

It is further preferable that the second carrier plate can be exchanged. In an exchange a carrier plate with a single protrusion could be exchanged for a carrier plate with four or more protrusions. This allows that the mechanical force can be directed at different areas of a substrate. The application of the mechanical force to limited areas of the substrate is suitable for the manufacture of certain types of flat panel displays, such as those with a very large display element. The arrangement of the invention with an exchangeable second carrier plate is thus suitable for the manufacture or a wider range of flat panel displays.

In a further embodiment the first carrier is transparent for ultraviolet irradiation and it has a bottom and a top side. At this top side the first substrate can be provided. At this bottom side an irradiation source for providing the ultraviolet irradiation is present. Herein the apparatus for curing the sealing material is integrated into the arrangement for laminating the first and second substrate. This is very practical, also in view of the fact that for an electroluminescent display both laminating and curing have to be done under a vacuum or non-oxidizing atmosphere.

The arrangement may be further elaborated such that there is not only a cavity for fluid between the second substrate and the second carrier plate, but also between the first substrate and the first carrier plate.

A flat panel display of the kind mentioned in the opening paragraph is known from JP-A 2001-319775. The known flat panel display has a first and second substrate of glass. The first and second substrate are sealed to each other with a solder glass or another low melting glass as sealing material. This sealing material is heated by irradiating it locally with a laser beam. As a consequence it melts and fuses with the first and second glass plate.

It is a disadvantage that the melting of the solder glass is less easy to control. There is the risk that at some places the solder glass does not melt properly with the effect that the display is not sealed effectively. This risk is enhanced, since the local irradiation with a laser beam implies that the solder glass is not melted at one moment over the whole substrate. Since the solder glass will have a lower height after melting, this leads to variations in height during the melting procedure. This has the risks that the seal is not everywhere as tight as required and that tensions are introduced in the display, such that the lifetime of the display is shortened. It is therewith observed that the melting temperature cannot be too low in order that the flat display meets all stability requirements, such as that it can lie in a car with sun shining on it. Even if it is possible to provide the laser beam patternwise at once, the distance between the substrates is not easy to control, especially with large-sized substrates, such as 8 inch (20 cm) or larger.

It is a third object of the invention to provide a flat panel display of the kind mentioned in the opening paragraph with a good lifetime.

This object is realized in that the sealing material is curable and comprises spacers to keep the inner faces of the first and second substrate at a distance of at most 50 μm.

The flat panel display of the invention is found to be effective to limit the influence of moisture. It is preferred that the spacers keep the inner faces of the substrates at a distance of at most 20 μm. It is further preferred that a moisture absorbent is present between the first and second substrate. With this embodiment the limitation of the influence of moisture is also realized for display elements, in which the individual pixels are separated by protruding structures, for example of resist material. Such structures have as consequence that at their side faces the organic electroluminescent layer lies at the surface. This has the effect that the penetration of moisture is relatively easy as compared to the display element provided with a single, large pixel. Due to the homogeneous application of mechanical force in the method of the invention, and the small distance between the inner faces of the first and second substrates, the resulting flat panel display has nevertheless a good resistance against moisture and an excellent lifetime.

The flat panel display may be manufactured with a cavity for separation purposes. Such cavity allows a separation with sawing. Such separation will take place in such away that one of the faces of this cavity is taken away, therewith bringing interconnects to the surface of the display, which interconnects are used as contacts to the outer world. Such contacts may be provided alternatively as well, however.

These and other aspects of the method, the arrangement and the flat panel display of the invention will be further elucidated with reference to the figures, in which:

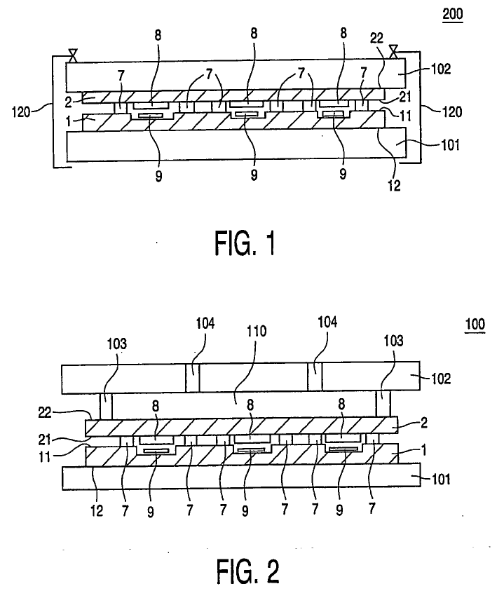

FIG. 1 shows a diagrammatical cross-section of a comparative arrangement during manufacture of a panel display;

FIG. 2 shows a diagrammatical cross-section of a first embodiment of the arrangement of the invention during the method of the invention;

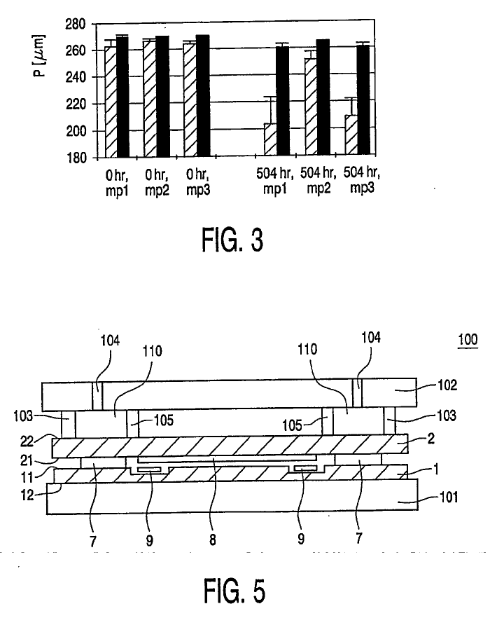

FIG. 3 shows a graphic of the lifetime of the displays obtainable from the methods as shown in FIGS. 1 and 2;

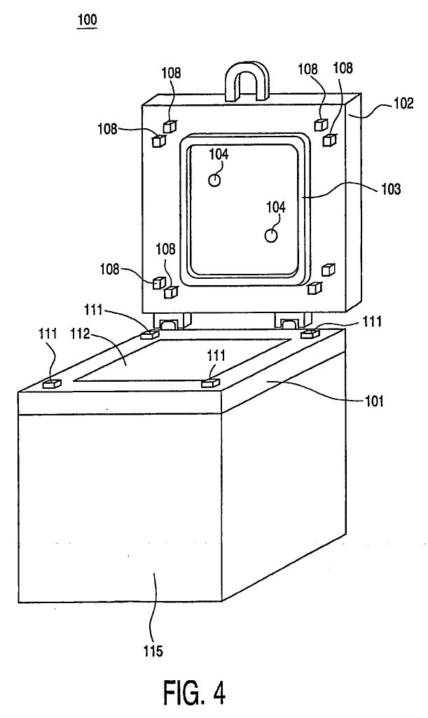

FIG. 4 shows a bird's eye perspective drawing of the arrangement of the invention; and

FIG. 5 shows a diagrammatical cross-section of a second embodiment of the arrangement of the invention.

The figures are not drawn to scale, like reference numbers in the figures refer to like parts.

FIG. 1 shows a comparative example of the arrangement 200, as used in experiments leading to the invention, with a first and a second glass substrate 1,2 therein present. The first substrate 1 and the second substrate 2 are each provided with an inner face 11,21 and an outer face 12,22. In between of these substrates 1,2 display elements 8 and lines of sealing material 7 are present. The display elements 8 have a thickness of about 2 μm, and the sealing material 7 has a substantially larger thickness. This sealing material 7 has been provided according to a desired pattern in a manner known to the skilled person, for instance with plotting, screen printing or spraying. The first substrate has deepened parts, in which moisture getters 9 are present. Such deepened parts can also be used to contain any superfluous amount of seating material. The display elements 8 are in this case electroluminescent display elements. The elements 8 have an electroluminescent organic layer disposed between a hole-injecting electrode and an electron-injecting electrode. Suitable materials for these layers are known per se to the person skilled in the art of electroluminescent displays.

The arrangement 200 is present in a non-oxidic and dry atmosphere. The pressure of the atmosphere may be varied; it is therewith preferred that while providing mechanical force with gas pressure, the pressure in the atmosphere is increased, so as to prevent large pressure differences. The first and the second substrate 1,2, as well as the sealing material 7, are present in this non-oxidic and dry atmosphere as well.

The first substrate 1 is positioned and fixed on a first carrier plate 101, that is in this case made of quartz, so that ultraviolet irradiation can be provided through the first carrier plate in order to cure the sealing material. The second substrate 2 is attached to the second carrier plate 102, which is made of metal. As the alignment of the first and second carrier plates 101,102 is not very critical, the first substrate 1 is positioned on the first carrier plate 101 by using—not-shown—pins. The second carrier plate 102 is thereafter moved towards the first carrier plate 101 while using direct mechanical force with the means 120. It has turned out that the mechanical force cannot be controlled and reproduced. There is further an unevenness in the second carrier plate 102, leading to locally a too high pressure. If the applied pressure is too high, white areas appear in the sealing material 7. These areas are characterized as bubbles, leading to a less tight seal.

FIG. 2 shows a cross-sectional view of the arrangement 100 of the invention. Also in this case the first and the second substrate 1,2 are present between the first carrier plate 101 and the second carrier plate 102. In this arrangement 100 an ring-shaped protrusion 103 is attached to the second carrier plate 102. When the second substrate 2 is present in the arrangement 100, the second substrate 2, the ring-shaped protrusion 103 and the second carrier plate define a cavity 110. Fluid can be provided into the cavity through apertures 104 in the second carrier plate 2. This fluid is preferably a inert gas, such as nitrogen or argon. After the provision of the fluid into the cavity 110, the sealing material 7 is exposed to ultraviolet irradiation. This irradiation preferably originates from a source that is present under the first carrier plate 101. Thereafter, the gas pressure is removed and the resulting stack is taken out of the arrangement 100. Then it is separated into individual flat panel displays.

In the experiments done, nitrogen was used as gas. The gas pressure was set to a value between 0.2 and 0.4 bar, which however can vary with the specific arrangement used. Therewith the mechanical force was applied homogeneously over the second substrate 2. The homogeneity of the mechanical force was proved in that no white areas appeared in the sealing material 7.

In the present example, which is however not necessary, the sealing material was an organic glue, such as an epoxy-based adhesive or high-molecular, halogenated or non-halogenated hydrocarbons. The sealing material contained spacers that has an average diameter of 10 μm with a deviation of 0.2 μm. This resulted therein that the distance between the inner faces 11,21 of the first and second substrate 1,2 was about 12 μm. It was found that with the method of the invention there is a very limited spreading within the width of the patterns of sealing material. This is considered to be a sign that the pressure has been applied homogeneously. It further has the advantage, that the amount of sealing material can be controlled very well. The problem as mentioned in JP 2001-189191 that a superfluous amount of sealing material may thus come into contact with the display element, is thus substantially absent.

FIG. 3 shows a histogram with measurement results of flat panel displays obtained with the use of the arrangements 200 and 100 as shown in FIGS. 1 and 2. In this figure, the dashed bars indicate the results for the display obtained with the use of the comparative arrangement 200. The black bars indicate the results for the display obtained with the method and the arrangement 100 of the invention. As characteristic value the pixel size P is used. On the left side of the histogram the sizes of three pixels of the displays directly after manufacturing are shown. The three chosen pixels were present in the left region, in the middle and in the right region of the display On the right side of the histogram the sizes of the same pixels is shown after an extreme lifetime test. In this test the displays were brought to a temperature of 85° C. and a humidity of 85% during 21 days.

As shown, the sizes of the pixels of the display obtained with the comparative arrangement 200 shrink during the lifetime test. The pixels in the left and right regions have shrunk about 20%. The pixel in the middle has shrunk between 5 and 10%. Contrarily, the pixels in the display obtained with the method of the invention do not or hardly shrink during the lifetime test. This shows that the method of the invention provides a substantial advantage over the prior art. It is further observed that the pixels in the left and right regions of the display obtained with the comparative arrangement 200 have shrunk already before the lifetime test has begun.

FIG. 4 shows a bird's eye perspective drawing of the arrangement 100 of the invention. The first carrier plate 101 is herein present on a box 115 comprising a source for ultraviolet irradiation. The surface 112 of the first carrier plate 101 is made of quartz and transparent. On the first carrier plate 101 positioning means 111 are present. These positioning means are for example pins. The not-shown first substrate 1 can be provided with its outer face 12 at the surface 112.

The second carrier plate 102 is attached to the first carrier plate 101 with a connection such that it can be opened and closed manually. However, it will be clear to the skilled person, that an embodiment according to which the second carrier plate 102 is moved mechanically, is possible as well. A ring-shaped protrusion 103 is attached to the second carrier plate 102. Its attachment is realized in that it is anchored mechanically. Apertures 104 are present in the second carrier plate 102 to allow fluid to enter into the cavity that can be formed between the protrusion 103. Alternatively the supply of fluid may be provided as an aperture in the protrusion 103 or between the second carrier plate 102 and the protrusion 103. At the backside of the second carrier plate 102 a pipe is attached to the apertures 104 and there are provided mechanical means, with which the first and the second carrier plate 101,102 are pushed together.

At the shown side of the second carrier plate 102 attachment means 108 are present to attach the not-shown second substrate 2 with its outer face 22. The attachment means 108 preferably allow at the same time a correct aligning of the second substrate 2 with the first substrate 1. They may for instance contain elevated parts at the outside. The attachment means 108 have substantially the same or a somewhat reduced height in comparison to the protrusions 103. This is to ensure that there is no space between the second substrate 2 and the protrusions 103. The attachment between the second substrate and the attachment means 108 can be realized with a reduced pressure, e.g. in that there are further apertures in the second carrier plate 102 to provide the reduced pressure. Alternatively, the attachment means 108 can be made very flat, with the effect of attraction. It can further be that they are provided with an upper and a lower part, in between of which the second substrate 2 is clamped.

FIG. 5 shows a second embodiment of the arrangement 100 of the invention. This arrangement 100 is in particular suitable for the lamination of substrates 1,2 in between of which a display element with a large diameter is present. In this embodiment, there is attached an inner ring-shaped protrusion 105 to the second carrier plate 102. The cavity 100 is therewith limited between the second substrate 2, the second carrier plate 102 and the protrusions 103, 105. In this manner the gas pressure is only provided at the areas where lamination of the substrates 1,2 must take place, e.g. at the areas where sealing material 7 is provided.

1. A method of manufacturing a flat panel display comprising a first and a second substrate in between of which a display element is present, the substrates having an inner face and an outer face and facing each other with their inner faces, which method comprises the steps of:
providing a sealing material at the inner face of at least one of the substrates;
laminating the substrates by applying a mechanical force at the outer face of at least one of them, and
curing the sealing material,
characterized in that a fluid is provided at the outer face of the second substrate to apply the mechanical force homogeneously over the substrate.

2. A method according to claim 1, characterized in that
an arrangement having a first and a second carrier plate is provided, to which second carrier plate a ring-shaped protrusion is attached;
the first substrate is provided with its outer face on the first carrier plate,
the second substrate is attached with its outer face to the second carrier plate, such that a cavity is present between the second substrate, the second carrier plate and the ring-shaped protrusion, and
the fluid is provided into the cavity.

3. A method according to claim 2, characterized in that the cavity is further bounded by an inner ring-shaped protrusion which is attached to the second carrier plate, so as to provide mechanical force at limited areas of the second substrate only.

4. A method according to claim 2, characterized in that a second cavity is present between the second substrate and the second carrier plate, the second cavity being bounded by a second ring-shaped protrusion that is attached at the second carrier plate.

5. A method as claimed in claim 1, characterized in that
the first and second substrates are made of glass and
a cavity is provided into the first substrate wherein the display element is provided.

6. A method as claimed in claim 5, characterized in that the sealing material comprises spacers, so as to bring the first and second substrate at a predetermined distance of each other, which distance is at most 10 μm.

7. A method as claimed in claim 1, characterized in that
a plurality of display elements is provided between the first and the second substrate and
after laminating the first and second substrates and curing the sealing material, the resulting substrate stack is separated into individual flat panel displays.

8. An arrangement for laminating a first and a second substrate in between of which a display element is present, provided with a first carrier plate for the first substrate and a second carrier plate to which the second substrate can be attached, and means for moving the carrier plates towards each other to laminate the first and second substrate, characterized in that the second carrier plate is provided with:
mechanical attachment means such that after attaching the second substrate a cavity is present between the second substrate and the second carrier plate,
a ring-shaped protrusion, that acts as side-wall of the cavity, and
supply means to provide a fluid into the cavity.

9. An arrangement as claimed in claim 8, characterized in that a second ring-shaped protrusion is attached to the second carrier plate, to act as an inner boundary of the cavity or to define a second cavity.

10. An arrangement according to claim 8, wherein
the first carrier plate is transparent for ultraviolet irradiation, and
the first carrier plate has a bottom and a top side at which top side the first substrate can be provided and at which bottom side an irradiation source for providing ultraviolet irradiation is present.

11. A flat panel display comprising a first and a second glass substrate in between of which a electroluminescent display element with an organic electroluminescent layer is present, the substrates having an inner face and an outer face and facing each other with their inner faces and being laminated together with a layer of sealing material, the display element being hermetically enclosed by the first and the second substrate and the layer of sealing material, characterized in that the sealing material is curable and comprises spacers to keep the first and second substrate at a distance of at most 50 μm.
